(19) United States
(12) Patent Application Publication
(10) Pub. No.: US 2008/0315751 A1
(43) Pub. Date: Dec. 25, 2008

(54) Aryl-substituted conjugated polymers

(75) Inventors: Elena Sheina, Pittsburgh, PA (US); Darin Laird, Pittsuburgh, PA (US)

Correspondence Address: FOLEY AND LARDNER LLP;SUITE 500, 3000 K STREET NW, WASHINGTON, DC, 20007, US

(73) Assignee: Plextronics, Inc.

(21) Appl. No.: 12/153,181

(22) Filed: May 14, 2008

Related U.S. Application Data
(60) Provisional application No. 60/938,166, filed on May 15, 2007.

(51) Int. Cl. H01J 1/62; C08G 75/00; C08K 3/04; H01L 31/00

(52) U.S. Cl. 313/503; 528/380; 524/495; 136/252; 977/735

(57) ABSTRACT

Aryl-substituted conjugated polymers are described having improved properties. The polymers include a polymer backbone that includes heterocyclic repeat units. At least some of the heterocyclic repeat units have an aryl substituent attached thereto and at least some of these aryl substituents have a branched alkyl substituent attached thereto. The conjugated polymer are well-suited for use in a variety of electronic devices, including photovoltaic cells, light-emitting diodes, and transistors. Tunability of material, spectroscopic, and/or electronic properties is possible.

### RELATED APPLICATIONS

This application claim priority to provisional application Ser. No. 60/938,166 filed May 15, 2007, which is hereby incorporated by reference in its entirety.

### BACKGROUND

Organic materials provide exciting prospects for applications in electronic devices including, for example, printed electronics, solar cells, light-emitting diodes, and thin film transistors. In particular, solar cells (or photovoltaic devices) are important because an economic need exists for a practical source of renewable energy that will substantially reduce dependence upon fossil fuels. Silicon-based solar energy systems have been touted for years as a potential candidate. However, the capital-intensive nature of silicon manufacturing processes contributes to a cost structure that falls significantly short of commercial viability. Photovoltaic cells, or solar cells, based on Inherently Conductive Polymers (ICPs) (or conducting polymers or conjugated polymers such as polyacetylene, polythiophene, polyaniline, polypyrrole, polyfluorene, polyphenylene, and poly(phenylene vinylene) offer great potential as significantly lower-cost devices because these polymers can be handled like inks in conventional printing processes.

Alternative sources of energy, especially renewable energy, are being sought to dramatically change the functional and cost boundaries resulting from current energy sources. This need is heightened by the rapidly increasing cost, environmental impact, and geo-political implications of the world's reliance on fossil fuels. Regulations from the global (e.g., Kyoto) to the local level increase the demand for cost-effective renewable energy supply. The use of the sun's rays to create power represents an attractive, zero-emission source of renewable energy.

Silicon-based solar cells, first demonstrated over 50 years ago (Perlin, John, “The Silicon Solar Cell Turns 50,” NREL 2004), are the primary technology in the current $5 billion solar cell market. However, the installed cost of this technology is approximately five to ten times that of traditional power sources. Thus, its cost/performance structure does not facilitate broad market adoption. As a result, solar energy accounts for much less than 1 percent of the nation's current energy supply. In order to expand this reach, and meet the growing need for renewable energy sources, novel alternative technologies are required.

Conductive polymers are a key component of a new generation of solar cells that promises to significantly reduce the cost/performance barrier of existing solar cells. The primary advantage of a conductive polymer solar cell is that the core materials, and the device itself, can be manufactured in a low-cost manner. The core materials—similar to plastics—are made in industrial-sized reactors under standard thermal conditions. They can be solution processed to form thin films or printed by standard printing techniques. Thus, the cost of operating a manufacturing plant is significantly less expensive than the cost of operating a silicon fabrication facility. This creates a low total-cost solar cell manufacturing platform. Furthermore, conductive polymer solar technology presents flexible, light-weight design advantages compared to silicon-based solar cells. While this technology holds great promise, commercialization hurdles remain. A need exists to find compositions which substantially improve performance. For example, a need exists to develop better polymers with better tunability such as, for example, low band gaps and/or deeper HOMOs (Highest Occupied Molecular Orbitals). Moreover, materials are needed which show better stability and reproducible properties.

### SUMMARY

Monomers, polymers and compositions, methods of making and using the same, and devices and articles incorporating the same are described herein.

Specifically, the present invention provides monomers comprising a heterocyclic ring, such as a thiophene ring, having an aryl side group, such as a phenyl group, wherein the aryl side group comprises a branched alkyl substituent, such as an ethylhexyl group. Conjugated polymers made from the monomers are also provided. These polymers include a conjugated polymer backbone comprising heterocyclic repeat units and side groups, wherein at least some of the side groups comprise an aryl group having at least one branched alkyl group substituent. The conjugated polymers may exhibit little or no thermochromism and improved electronic and optoelectronic (e.g., photovoltaic) properties compared with more conventional conjugated polymers, such as poly(3-hexylthiophene).

Electronic devices incorporating the conjugated polymers are also provided. Such devices include, but are not limited to, organic photovoltaic cells, organic light-emitting devices, and organic thin film transistors.

Advantages which can be obtained for one or more embodiments include, for example, materials having better stability; reduced or substantially absent or absent thermochromism; low band gap; deep HOMO; red shift absorption; solvato-chromic changes; better self assembly and solvent-induced aggregation; electronic tenability; electronic decoupling of at least part of the side group from the conjugated polymer backbone; and increase in the molar absorptivity.

### BRIEF DESCRIPTION OF THE DRAWINGS

FIG. 1 shows the UV-Vis-NIR spectra of spin cast films from chlorobenzene of: (a) a poly{3-[4-(2-ethylhexyl)phenyl]thiophene} and [6,6]-phenyl-C61-butyric acid methyl ester (PCBM) blend (1.5:1) before and after annealing at various temperatures; and (b) poly{3-[4-(2-ethylhexyl)phenyl]thiophene} before and after annealing at various temperatures.

FIG. 2 shows UV-Vis-NIR spectra of spin cast films from chlorobenzene of: (a) a poly{3-[4-(2-ethylhexyl)phenyl]thiophene} and [6,6]-phenyl-C61-butyric acid methyl ester (PCBM) blend (1.5:1) before and after annealing; and (b) a poly[3-(4-octylphenyl)thiophene] and [6,6]-phenyl-C61-butyric acid methyl ester (PCBM) blend (1.5:1) before and after annealing.

FIG. 3 shows UV-Vis-NIR spectra of spin cast films from chlorobenzene of p/n composite blends (1.5:1) of poly{3-[4-(2-ethylhexyl)phenyl]thiophene} and poly[3-(4-octylphenyl)thiophene] with [6,6]-phenyl-C61-butyric acid methyl ester (PCBM) before (a) and after annealing (b).

### DETAILED DESCRIPTION

In practicing the presently claimed inventions in their various embodiments, the following description of the technical literature and the various components can be used. The references cited throughout the specification, including the list at the end, are hereby incorporated by reference in their entirety.

Provisional patent application Ser. No. 60/612,640 filed Sep. 24, 2004, to Williams, et al. (“HETEROATOMIC REGIOREGULAR POLY(3-SUBSTITUTED THIOPHENES) FOR ELECTROLUMINESCENT DEVICES”), and U.S. Ser. No. 11/234,374 filed Sep. 26, 2005, are hereby incorporated by reference in their entirety, including the description of the polymers, the figures, and the claims.

Provisional patent application Ser. No. 60/612,641 filed Sep. 24, 2004, to Williams, et al. (“HETEROATOMIC REGIOREGULAR POLY (3-SUBSTITUTED THIOPHENES) FOR PHOTOVOLTAIC CELLS”), and U.S. Ser. No. 11/234,373 filed Sep. 26, 2005, are hereby incorporated by reference in their entirety, including the description of the polymers, the figures, and the claims.

Provisional patent application Ser. No. 60/651,211 filed Feb. 10, 2005, to Williams, et al. (“HOLE INJECTION LAYER COMPOSITIONS”), and U.S. Ser. No. 11/350,271 filed Feb. 9, 2006, are hereby incorporated by reference in their entirety, including the description of the polymers, the figures, and the claims.

Priority provisional patent application Ser. No. 60/661,934 filed Mar. 16, 2005, to Williams, et al., and U.S. Ser No. 11,376/550 filed Mar. 16, 2006, are hereby incorporated by reference in their entirety, including the description of the polymers, the figures, and the claims.

Provisional patent application Ser. No. 60/812,916 filed Jun. 13, 2006 (“ORGANIC PHOTOVOLTAIC DEVICES COMPRISING FULLERENES AND DERIVATIVES THEREOF”), and U.S. patent application Ser. No. 11/743,587 filed May 2, 2007, are hereby incorporated by reference in their entirety, including the descriptions of the polymers, the n-components including indene derivatives, the figures and the claims.

Provisional patent application Ser. No. 60/915,632 filed May 2, 2007 (“SOLVENT BLENDS IN ACTIVE LAYER CONDUCTING POLYMER TECHNOLOGY FOR PRINTED ELECTRONIC DEVICES”) is hereby incorporated in its entirety, including the description of the polymers, the solvent blends, the figures and the claims.

This invention relates to aryl-substituted conjugated polymers having improved properties. The polymers include a polymer backbone that includes heterocyclic repeat units. At least some of the heterocyclic repeat units have an aryl substituent attached thereto and at least some of these aryl substituents have a branched alkyl substituent attached thereto. Without wishing or intending to be bound to any particular theory of the invention, the inventors believe the improved properties of the polymers may be attributed to the minimization or elimination of thermochromism in the polymers, to the improved solubility and processability of the polymers relative to alkyl-substituted polymers and other aryl-substituted polymers wherein the aryl ring has an unbranched substituent, to an increase in the intermolecular and/or intramolecular order of the polymers and improved polymer mixing to provide polymer materials having improved morphologies, thermal stabilities and/or packing densities, or to a combination of these effects.

Thermochromism, the reversible change in the color of a polymer as its temperature is varied, indicates a temperature-dependent change in the structure and/or morphology of the polymer. The minimization or elimination of thermochromism in conjugated polymers is particularly desirable because it provides conjugated polymers having structures, morphologies and/or electronic and optoelectronic properties that are more reproducible than conjugated polymers that display a significant degree of thermochromism. Reproducibility of polymer morphologies and properties is a very important characteristic for conjugated polymers if they are to be incorporated into electronic devices on a commercial scale. By way of illustration, the inventors have demonstrated that aryl-substituted polythiophenes having a branched alkyl substituent on the aryl side group exhibit zero or substantially zero thermochromism. In contrast, aryl-substituted polythiophenes having a straight-chain alkyl substituent on the aryl side group exhibit significant thermochromism, resulting in non-reproducible or less reproducible electronic and optoelectronic properties. This is illustrated for one exemplary embodiment in Example 10.

For the purposes of this disclosure, a polymer film may be said to exhibit substantially zero theromochromism if the absorbance peak (or peaks) for the annealed polymer film shifts by no more than 10 nm, desirably no more than 5 nm, and more desirably no more than 1 nm relative to the absorbance peak (or peaks) for the polymer film as cast at room temperature (i.e., pre-annealing). The absence or substantial absence of thermochromism for a polymer film may be tested for polymer films cast from a variety of solvents at a variety of annealing temperatures and annealing durations. For example, the absence or substantial absence of thermochromism in a polymer film may be tested after annealing a film cast from chlorobenzene at a temperature of 70° C. for 30 minutes, after annealing the film at a temperature of 140° C. for 10 minutes, or after annealing the film at a temperature of 200° C. for 10 minutes. In some embodiments, the polymer films that exhibit zero or substantially zero thermochromism include an n-type component (as described in greater detail below), while in other embodiments the n-type component is absent. Examples of suitable test conditions are provided in Example 10, below.

In addition to the advantages listed above, the present aryl substituents provide polymers that may be used to modify the energy levels of the polymers to suit a desired end-use application. More specifically, the aryl substituents may provide polymers having a lower (deeper) highest-occupied molecular orbital (“HOMO”) than a corresponding alkyl-substituted polymer. In applications such as polymer-based solar cells, polymer light-emitting diodes, organic transistors, or other organic circuitry, the flow of electrons and positive conductors (i.e. “holes”) is dictated by the relative energy gradient of the conduction and valence bands within the components. Therefore, suitable conjugated polymers for a given application are selected for the values of their energy band levels which may be suitably approximated through analysis of ionization potential (as measured by cyclic voltammetry) (Micaroni, L., et al., J. Solid State Electrochem., 2002, 7, 55-59 and references sited therein) and band gap (as determined by UV/Vis/NIR spectroscopy as described in McCullough, R. Adv. Mater., 1998, 10, No. 2, pages 93-116, and references cited therein). Thus, the ability to produce conjugated polymer having modified energy levels provides an important advantage in the design and fabrication of a variety of electronic devices, including photovoltaic cells, light-emitting diodes, and transistors.

The present invention provides the aryl-substituted, conjugated polymers, methods of making the polymers, and electronic devices that incorporate the polymers. Each of these aspects of the invention is described in greater detail below.

Aryl-Substituted Conjugated Polymers

The conjugated polymers can be described as inherently conductive. Inherently conductive polymers (ICPs) are polymers that, due to their conjugated backbone structure, show electrical conductivities including high electrical conductivities under some conditions (relative to those of traditional polymeric materials). Performance of these materials as a conductor of holes or electrons is increased when they are doped, oxidized, or reduced. Upon low oxidation (or reduction) of ICPs, in a process which is frequently referred to as doping, an electron is removed from the top of the valence band (or added to the bottom of the conduction band) creating a radical cation (or polaron). Formation of a polaron creates a partial delocalization over several monomeric units. Upon further oxidation, another electron can be removed from a separate polymer segment, thus yielding two independent polarons. Alternatively, the unpaired electron can be removed to create a dication (or bipolaron). In an applied electric field, both polarons and bipolarons are mobile and can move along the polymer chain by delocalization of double and single bonds. This change in oxidation state results in the formation of new energy states, called bipolarons. The energy levels are accessible to some of the remaining electrons in the valence band, allowing the polymer to function as a conductor.

In addition, electrically conductive polymers are described in The Encyclopedia of Polymer Science and Engineering, Wiley, 1990, pages 298-300, including polyacetylene, poly(p-phenylene), poly(p-phenylene sulfide), polypyrrole, and polythiophene, which article is hereby incorporated by reference in its entirety. This reference also describes blending and copolymerization of polymers, including block copolymer formation.

The present polymers include a conjugated backbone that includes heterocyclic repeat units and side groups attached to at least some of the heterocyclic repeat units. At least some of the side groups on the heterocyclic repeat units are aryl groups which are desirably attached directly to the aryl rings, where “aryl” refers to a cyclic, aromatic arrangement of carbon atoms forming a ring. At least some of the aryl groups have at least one branched alkyl substituent attached thereto. Since the electronic properties of the inherently conductive polymer arise from the conjugated band structure of the polymer backbone, any substituents that increase or decrease the electron density within the backbone π-structure directly affect the band gap and energy levels of the polymer. Therefore, the present aryl substituents, which contain electron withdrawing substituents, will reduce the electron density of the conjugated backbone and deepen the HOMO of the polymer. The magnitude of the change in energy levels of the polymer depends upon the specific functionality of the substituent, the proximity or nature of attachment of the functionality to the conjugated backbone, as well as the presence of other functional characteristics within the polymer.

The polymer backbone may be homopolymeric or copolymeric. Copolymeric polymer backbones are those that include at least two different repeat units. In these embodiments, monomers other than those containing the aryl-substituted heterocyclic repeat units having a branched alkyl substituent on the aryl ring are referred to as comonomers. The copolymers may be block, alternating, graft or random copolymers and the comonomers may be non-heterocyclic, substituted heterocyclic and/or unsubstituted heterocyclic. For example, the block copolymers may be AB type or ABA type. The number of different comonomers in the copolymers may be one, two, three, or more. In some embodiments, the polymer is a copolymer that includes differently-substituted thiophene rings and/or a combination of substituted and unsubstituted thiophene rings.

Polythiophenes, and particularly regioregular polythiophenes, are well-suited for the present applications because polythiophenes have a conjugated π-electron band structure that makes them strong absorbers of light in the visible spectrum and hence a candidate p-type semiconductor for photovoltaic cells. In the case of poly(3-alkyl thiophenes), the alkyl substituents that are typically included to increase solubility of the polymer in common organic solvents have an electron-releasing effect, raising the HOMO of the polymer relative to that of poly(thiophene). Unfortunately, for an application in which a deep HOMO is required, this electron-releasing functionality imparts the opposite of the desired electronic effect. Therefore, the present aryl-substituted polymers, which offer the possibility of balancing the electronic, optical, and physical properties of conjugated polymers (and polythiophenes, in particular) provide materials that satisfy diverse performance requirements and offer a real advantage in organic device development.

The polythiophenes may be, for example, polythiophenes having the following structure:

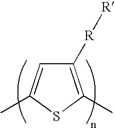

where R is an aryl group, R′ is a branched alkyl group, and n represents the number of thiophene repeat units in the polymer backbone. The thiophene repeat units may be adjacent (as in the case wherein the polymer backbone is homopolymeric) or may be separated by other backbone units (as in the case wherein the polymer backbone is copolymeric (e.g., block co-polymeric)). Typically, n has a value of about 5 to about 3,000, or about 10 to about 1,000, or about 10 to about 300, or about 50 to about 200. Although the structure above shows the thiophene ring substituted with an aryl group at the 3-position, the ring could be substituted with an aryl group at positions other than, or in addition to, the 3-position. For example, the aryl group may be located at the 4-position of the heterocyclic ring.

Preferred aryl side groups, R, include, but are not limited to phenyl groups. An aryl group can be optionally substituted with 1 to 4, 1 to 3, or 1 to 2, or one group selected from, for example, lower alkyl, alkoxy, halo, sulfonyl, sulfonate, cyano, or nitro.

Preferred branched alkyl groups, R, include branched alkyl groups having four or more carbon atoms. For example, the branched alkyl group may be a C₃-C₂₀ alkyl group, a C₄-C₁₂ alkyl group, or a C₅-C₁₀ alkyl group. Examples of branched alkyl groups include, but are not limited to, for example ethyl hexyl groups, isopropyl, iso-butyl, sec-butyl, tert-butyl, neopentyl, or isopentyl. In one specific embodiment, the aryl side group is a phenyl group and the branched alkyl substituent in a 2-ethylhexyl group. The branched alkyl group can have at least one chiral center. The chiral center can be in an R configuration or an S configuration. Polymers comprising the chiral center in the side group can have mixtures of both R and S configurations on the same polymer chain. The R and S configurations can be distributed randomly along the polymer chain. In another embodiment, the aryl side group is a phenyl group having at least two branched alkyl substituents. For example, the phenyl group may have two ethyl hexyl groups at, for example, the meta positions.

In addition to the branched alkyl-substituted aryl side group, the heterocyclic rings of the backbone may have other additional side groups. For example, additional substituents at other ring positions may include, but are not limited to, H, Cl, Br, I, F, optionally substituted alkyl, optionally substituted aryl, optionally substituted alkylaryl, optionally substituted alkoxy, optionally substituted aryloxy, optionally substituted alkylene oxide, optionally substituted alkylene, functionalized alkyl, functionalized aryl, functionalized alkylaryl, functionalized alkoxy, functionalized aryloxy, functionalized alkylene oxide, or functionalized alkylene. Therefore, these additional substituents may be linear, branched, heteroatomic substituted, oligomeric, polymeric, or may contain one or more halogen, hydroxyl, carboxylic acid, amide, amine, nitrile, ether, ester, thiol, thioether, and like groups.

The present polymers may be made using a variety of methods, including the McCullough method, the GRIM method, and the universal GRIM method, each of which can be modified in ways known to those skilled in the art. Modifications to the chosen method are chosen based on the selected monomers. A description of these methods may be found in, for example, McCullough et al., J. Org. Chem., 1993, 58, 904-912, U.S. Pat. No. 6,602,974 to McCullough, et al., and U.S. Pat. No. 6,166,172 to McCullough, et al., are hereby incorporated by reference in their entirety. Additional description can be found in the articles, “The Chemistry of Conducting Polythiophenes,” McCullough, Adv. Mater., 10, No. 2, 93-116, and references cited therein, and Lowe, et al., Adv. Mater. 1999, 11, 250, which are hereby incorporated by reference in its entirety. The Handbook of Conducting Polymers, 2nd Ed., 1998, Chapter 9, by McCullough, et al., “Regioregular, Head-to-Tail Coupled Poly(3-alkylthiophene) and its Derivatives,” pages 225-258, is also hereby incorporated by reference in its entirety. A description of various embodiments for the Universal GRIM method is provided in U.S. Provisional Patent Application No. 60/841,548, filed on Sep. 1, 2006 to McCullough et al. Details with regard to each of these methods are provided in the Working Examples section below. By way illustration, a substituted polythiophene may be made using a modified universal GRIM method by dissolving a soluble thiophene monomer having at least two leaving groups in a solvent to form a mixture. The soluble thiophene monomer includes an aryl side group which includes a branched alkyl substituent. An organomagnesium reagent and a nickel (Ni(II)) reagent that may act as an initiator or a catalyst, are added to the mixture. The resulting substituted polythiophene may then be recovered.

Other appropriate polymerization methods can be used including, for example, oxidative polymerization or transition metal promoted cross coupling of organic dihalide derivatives of functionalized thiophenes. For oxidative polymerization, ferric chloride can be used as catalyst. Examples of transition metal promoted cross coupling include Suzuki coupling, Stille coupling, and Nigishi coupling.

Solvent Removal/Film Formation

Conventional methods can be used to cast polymer films from compositions containing the polymers to provide thin film forms and printed forms. For example, the conjugated polymers can be dissolved or dispersed in a suitable solvent, and then coated onto a substrate and allowed to dry. The resulting film may comprise a solvent, may be substantially free of solvent, or may be free of solvent. For example, the amount of solvent remaining in the film may be less than about 5% by weight, less than about 1% by weight, or less than about 0.1% by weight. The solvent may include any solvent or combination of solvents in which the polymers are sufficiently soluble. Examples of suitable solvents include, but are not limited to, aromatic solvents or compounds (including haloaromatic or halogenated aromatic solvents or compounds) and chlorinated solvents. Specific examples of suitable solvents include chlorobenzene, 1,2-dichlorobenzene, chloroform, 1,2-dichloroethane, 1,1,2,2-tetrachloroethane, dichloromethane, carbon tetrachloride, toluene, xylene, cyclohexanone, ethylacetate, cresol, butyrolacetone, dimethylformamide, and combinations thereof. Suitable coating methods include roll coating, screen printing, spin casting, spin coating, or ink jet printing, and other known coating and printing methods. Other methods are described in the references cited herein. The thickness of the film coating on the substrate can be, for example, about 10 nm to about 500 nm, or about 50 nm to about 250 nm, or about 100 nm to about 200 nm.

Optionally, the resulting films may be thermally annealed as desired. The annealing temperature and time can be adjusted to achieve a desired result. The annealing temperature can be, for example, about 100° C. to about 200° C., or about 100° C. to about 150° C. The annealing temperature can be below the melting temperature of the conjugated polymer. The annealing temperature can be, for example, below, at, or above the glass transition temperature of the conjugated polymer. The annealing temperature can be, for example, about 5° C. to about 60° C. above the glass transition temperature.

Optionally, the composition from which films of the polymer are cast may include an n-type component, an electron acceptor, or an electron acceptor moiety. These are materials with a strong electron affinity and good electron accepting character. The n-type component should provide fast transfer, good stability, good solubility, and good processability. The n-type component may take the form of particles, including microparticles and nanoparticles, inorganic particles, organic particles, and/or semiconductor particles. The n-type component can be a molecular material or a non-polymeric material having a molecular weight less than about 2,000 g/mol or less than about 1,000 g/mol. Specific examples of n-type components or moieties include, but are not limited to, carbon fullerenes, fullerene derivatives, carbon nanotubes, soluble fullerenes, titanium dioxide, cadmium selenide, and perylenes or perylene derivatives. Methanofullerene [6,6]-phenyl C₆₁-butyric acid methyl ester (PCBM), C₆₀-indene mono adduct, and C₆₀-indene bis-adduct are preferred examples of n-type components.

The weight ratio between the conjugated polymer and the n-type component in the composition can be controlled to achieve the desired electronic or optoelectronic (e.g., photovoltaic) effect. For example, the weight ratio of the polymer to the n-type component in the composition may be about 10:1 to about 0.5:1. This includes embodiments where the weight ratio is about 9:1 to 1:1 and further includes embodiments where the weight ratio is about 3:1 to about 1:1. Another range is about 1:2 to about 2:1. The amount can be tailored with one or more other parameters such as, for example, molecular weight, solvent selection, casting or coating conditions, and annealing temperature and time.

Electronic Devices

Examples of devices into which the present polymers may be incorporated include, but are not limited to, organic photovoltaic cells, photoluminescent devices (e.g., organic light emitting diodes), and transistors.

Solar Cells

A conductive polymer solar cell can be fabricated in a variety of embodiments known in the art and can, for example, comprise five components. A transparent electrode such as indium tin oxide (ITO) coated onto plastic or glass can function as the anode. It can be approximately 100 nm thick and allow light to enter the solar cell. The anode can be coated with up to 100 nm of a hole injection layer (HIL). The HIL can planarize the ITO surface and facilitate the collection of positive charge carriers (holes) from the light-harvesting layer to the anode. The opposite electrode, or cathode, can be made of a metal such as calcium or aluminum, and is typically, for example, 70 nm thick or more. It may include a thin conditioning layer (e.g. less than 1 nm of lithium fluoride) that can increase the lifetime and performance of the solar cell. In some cases, the cathode may be coated onto a supporting surface such as a flexible plastic or glass sheet. This electrode can carry electrons out of the solar cell and complete the electrical circuit.

The polymer materials may be used as the active layer of the solar cell, which is disposed between the hole injection layer and the cathode. There can be a junction between the conjugated polymer and n-type components (as described above) in the active layer. The conjugated material (i.e., the p-type material) is often referred to as the light-harvesting component. This material absorbs a photon of a particular energy and generates an excited state in which an electron is promoted to an energy state known as the Lowest Unoccupied Molecular Orbital (“LUMO”), leaving a positive charge or “hole” in the ground state energy level (the HOMO). This process is known as exciton formation. The exciton diffuses to a junction between the p-type and n-type materials, creating a charge separation or dissociation of the exciton. The electron and “hole” charges are conducted through the n-type and p-type materials, respectively, to the electrodes, resulting in the flow of electric current out of the cell. In the case of a photovoltaic or solar cell, the use of the present polymers helps maximize the potential difference, as indicated by the open-circuit voltage (V_{OC}) of the photovoltaic device, between the LUMO of the n-type semiconductor and the HOMO of the p-type semiconductor, while maintaining the solubility and polarity of the p-type semiconductor, such that these characteristics are comparable to those of high-performing, p-type semi-conductors such as regioregular poly(3-hexylthiophene). This is accomplished by placing the aryl substituent on the thiophene rings, which reduces the HOMO by decreasing the amount of electron-releasing character of the thiophene monomeric units.

In one embodiment, both the active layer and the hole injection layer of the photovoltaic cell can comprise polythiophenes, preferably regioregular polythiophenes.

The properties of a solar cell may be measured by various parameters, including the fill factor, FF, the current density at short circuit, J_{sc}, and the photovoltage at open circuit, V_{oc}. The use of the present aryl-substituted conjugated polymers in an organic photovoltaic (OPV) cell can provide an OPV having an increased V_{oc} relative to a control OPV made with a more conventional conjugated polymer. For example, the present aryl-substituted polythiophenes can provide an OPV with a V_{oc} that is at least 10% greater, at least 20% greater, at least 30% greater, or even at least 35% greater than the V_{oc} of a control OPV made with poly(3-hexyl thiophene) or with poly[3-(4-octyl phenyl)thiophene] as the conjugated polymer, wherein the comparison is between films having the same, or substantially the same thickness, which have been processed under the same conditions (e.g., the same annealing conditions) and which have been made by the same general method (e.g., GRIM, McCullough, etc.). This is illustrated in Examples 11 and 12.

The present aryl-substituted polythiophenes also can provide OPV cells with power conversion efficiencies that are higher and more reproducible than those of OPV cells made with more conventional conjugated polymers. For example, the present aryl-substituted polythiophenes can provide an OPV cell with an ρ% that is at least two times, at least 5 times, or even at least 10 times as high as that of a control OPV made with poly[3-(4-octyl phenyl)thiophene] as the conjugated polymer, wherein the comparison is between films having the same, or substantially the same thickness, which have been processed under the same conditions (e.g., the same annealing conditions) and which have been made by the same general method (e.g., GRIM, McCullough, etc.). In addition to providing higher overall efficiencies, the present aryl-substituted polythiophenes provide OPVs having efficiencies that are less dependent upon the thermal processing conditions and more resistant to high thermal processing temperatures.

Electroluminescent Devices

A typical electroluminescent device comprises four components. Two of these components are electrodes. The first electrode can be a transparent anode such as indium tin oxide coated onto a plastic or glass substrate, which functions as a charge carrier and allows emission of the photon from the device by virtue of its transparency. The second electrode, or cathode, is frequently made of a low-work-function metal such as calcium or aluminum, or both. In some cases, this metal may be coated onto a supporting surface such as a plastic or glass sheet. This second electrode conducts or injects electrons into the device. Between these two electrodes are the electroluminescent layer (EL) and the hole injection or hole transport layer (HIL/HTL).

The EL can comprise, for example, materials based on polyphenylene vinylenes, polyfluorenes, and organic-transition metal small molecule complexes. The present conjugated polymers could also be incorporated into the EL. These materials are generally chosen for the efficiency with which they emit photons when an exciton relaxes to the ground state through fluorescence or phosphorescence and for the wavelength or color of the light that they emit through the transparent electrode.

The present conjugated polymer material may be used as the HIL/HTLs. These are conducting materials that are able to transfer a positive charge or “hole” from the transparent anode to the EL, creating the exciton, which in turn leads to light emission.

The electroluminescent devices can take a variety of forms. The present devices, which comprise electroluminescent polymers, are commonly referred to as PLEDs (Polymer Light-Emitting Diodes). The EL layers can be designed to emit white light, either for white lighting applications or to be color-filtered for a full-color display application. The EL layers can also be designed to emit specific colors, such as red, green, and blue, which can then be combined to create the full spectrum of colors as seen by the human eye.

In the case of polymer-based, light-emitting diodes, it has been shown (see, for example, Shinar, J. Organic Light-Emitting Devices, Springer-Verlag New-York, Inc., 2004, and references incorporated therein) that matching the energy levels of the conducting polymer to that of the other components of the device is important for device performance. Therefore, many have sought to control the energy of the HOMO, and the LUMO, as well as the difference between these energy levels (a.k.a. the “band gap,” which also corresponds to the π-π* transition energy as observed through UV/Vis/NIR spectroscopy) through manipulation of the backbone structure of the conductive polymer (see, for example, Roncali, J., Chem. Rev. 1997, 97, 173.; Winder, C. et al., J. Mater. Chem., 2004, 14, 1077, and Colladet, K et al., Thin Solid Films, 2004, 7-11, 451, as well as the references incorporated herein). In the case of the hole-injection layer of a polymer-based, light-emitting polymer, the HOMO of a polythiophene (e.g., poly(3-hexylthiophene), P3HT) may be reduced in order to increase the energy level gradient of the transparent anode and the light-emitting polymer by using an aryl-substituted polymer in accordance with the present invention.

Thin Film Transistors

A typical thin film transistor includes a substrate; source and drain electrodes disposed over the substrate; a semiconductor layer, including the present conjugated polymer materials, disposed over the source and drain electrodes and the substrate; an insulating layer disposed over the conjugated polymer layer; and a gate electrode disposed over the insulating layer. This description is intended only to illustrate one embodiment of a typical thin-film transistor. Other configurations are possible, as is well-known by those skilled in the art.

In the case of an organic field-effect transistor, the invention can maximize the mobility of the p-type semiconductor while maintaining its solubility and polarity, such that these characteristics are similar to those of high-performing, p-type semiconductors such as regioregular P3HT. In one embodiment, this may be accomplished by the use of an aryl-substituted polymer in accordance with the present invention.

The following references can be used in practicing the various embodiments of the claimed inventions: (1) Brabec, et al., Adv. Func. Mater. 2001, 11, 374-380; (2) Sariciftci, N. S., Curr. Opinion in Solid State and Materials Science, 1999, 4, 373-378; (3) Sariciftci, N., Materials Today 2004, 36; (4) Hoppe, H. et al., J. Mater. Res. 2004, 19, 1924, (5) Nakamura, et al., Applied Physics Letters 2005, 87, 132105; (6) Paddinger et al., Advanced Functional Materials 2003, 13, No. 1, January, 85; (7) Kim, et al., Photovoltaic Materials and Phenomena Scell 2004, 1371, (8) J. Mater. Res., 2005, 20, No. 12, 3224; (9) Inoue, et al., Mater. Res. Soc. Symp. Proc., 836, L.3.2.1; (10) Li et al., J. Applied Physics 2005, 98, 043704.

Electrostatic Dissipation Coatings

Electrostatic dissipation coatings are described in for example U.S. provisional patent application Ser. No. 60/760,386 filed Jan. 20, 2006 to Greco et al., which is hereby incorporated by reference in its entirety including figures, claims, and working examples.

In one embodiment, the aryl-substituted polymer materials as described and claimed herein are employed in or as electrostatic dissipation (ESD) coatings, packaging materials, and other forms and applications. Electrostatic discharge is a common problem in many applications including electronic devices which are becoming smaller and more intricate. To combat this undesired event, conductive coatings, also known as ESD coatings, can be used to coat numerous devices and device components. Conductive materials can be also blended into other materials such as polymers to form blends and packaging materials. The polymer materials described herein may be used as the only polymeric component of an ESD coating or be combined (i.e., blended) with one or more additional polymers.

A non-limiting example of this embodiment involves a device comprising an electrostatic dissipation (ESD) coating, said ESD coating comprising at least one aryl-substituted conjugated polymer, as described herein. In another embodiment, provided is an ESD packaging material.

The coating may be a blend of one or more polymers. In these ESD coatings, where a polymeric blend is used, the polymers are preferably compatible and soluble, dispersible or otherwise solution processable in a suitable solvent. Thus, in addition to at least one aryl-substituted conjugated polymer, the coating may include one or more additional polymers. The additional polymer can be a synthetic polymer and is not particularly limited. It can be, for example, thermoplastic. Examples include organic polymers, synthetic polymers or oligomers, such as a polyvinyl polymer having a polymer side group, a poly(styrene) or a poly(styrene) derivative, poly(vinyl acetate) or its derivatives, poly(ethylene glycol) or its derivatives such as poly(ethylene-co-vinyl acetate), poly(pyrrolidone) or its derivatives such as poly(1-vinylpyrrolidone-co-vinyl acetate, poly(vinyl pyridine) or its derivatives, poly(methyl methacrylate) or its derivatives, poly(butyl acrylate) or its derivatives. More generally, it can comprise of polymers or oligomers built from monomers such as CH₂CH Ar, where Ar=any aryl or functionalized aryl group, isocyanates, ethylene oxides, conjugated dienes, CH₂CHR₁R (where R₁=alkyl, aryl, or alkylaryl functionality and R═H, alkyl, Cl, Br, F, OH, ester, acid, or ether), lactam, lactone, siloxanes, and ATRP macroinitiators. Preferred examples include poly(styrene) and poly(4-vinyl pyridine). Another example is a water-soluble or water-dispersable polyurethane.

The molecular weight of the polymers in the coating can vary. In general, for example, the number average molecular weight of the polymers can be between about 5,000 and about 50,000. If desired, the number average molecular weight of the polymers can be for example about 5,000 to about 10,000,000, or about 5,000 to about 1,000,000.

In any of the aforementioned ESD coatings, at least one polymer may be cross-linked for various reasons such as improved chemical, mechanical or electrical properties.

For proper dissipation of static electricity the conductivity of the coating can be tuned. For example, the amount of conjugated polymer can be increased or decreased. In addition, in some cases, doping can be used.

Application of the ESD coating can be achieved via spin coating, ink jetting, roll coating, gravure printing, dip coating, zone casting, or a combination thereof. Normally the applied coating is greater than 10 nm in thickness. Often, the coating is applied to insulating surfaces such as glass, silica, polymer or any others where static charge builds up. Additionally, the polymer material can be blended into materials used to fabricate packaging film used for protection of, for example, sensitive electronic equipment. This may be achieved by typical processing methodologies, such as, for example, blown film extrusion. Optical properties of the finished coating can vary tremendously depending on the type of blend and percent ratio of the polymers. Preferably, transparency of the coating is at least 90% over the wavelength region of 300 nm to 800 nm.

The ESD coatings can be applied to a wide variety of devices requiring static charge dissipation. Non-limiting examples include: semiconductor devices and components, integrated circuits, display screens, projectors, aircraft wide screens, vehicular wide screens or CRT screens.

Other examples of devices into which the present aryl-substituted polymers may be incorporated include sensors and shielding layers.

In addition to the description provided above, the following non-limiting examples are provided.

### WORKING EXAMPLE 1

### Synthesis of Monomers Used to Produce Aryl-Substituted Polythiopenes

This Example describes the methods used to produce the monomer reactants used to produce the aryl-substituted polythiophenes, as described in Examples 2-9.

### EXAMPLE 1a

### Synthesis of (2-ethylhexyl)-benzene

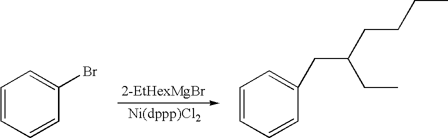

A dry 250-mL three-neck round bottom flask, equipped with a condenser and an addition funnel, was purged with N₂ and charged with bromobenzene (15 g, 0.10 mol), [1,3-bis(diphenylphosphino)propane]dichloronickel(II)(Ni(dppp)Cl₂) (0.27 g, 0.50 mol %). The reaction flask was cooled down to 0° C., whereupon (ethylhexyl)magnesium bromide 1 M solution in diethyl ether (100 mL) was added dropwise from the addition funnel over a 30-minute time period. The reaction was slightly exothermic, and a dark-brown color developed within minutes. The ice bath was replaced with an oil bath and the solution was heated up to gentle reflux and maintained at that temperature for 12 hours, then cooled in an ice bath, and quenched with cold HCl (100 mL, 1.0 N). The aqueous layer was separated and extracted with diethyl ether (3×100 mL). The combined organic phase was collected and dried over anhydrous magnesium sulfate (MgSO₄). After the product was filtered, the solvent was removed by rotary evaporation. The crude product was distilled under vacuum to yield 3.3 g (70%) of colorless oil.

Spectral data: ¹H NMR (300 MHz, CDCl₃): δ_{H}0.85 (t, J=6 Hz, 6H), 1.25 (m, 8H), 1.55 (m, 1H), 2.51 (d, J=7 Hz, 2H), 7.12 (m, 5H).

### EXAMPLE 1b

### Synthesis of 1-bromo-4-(2-ethylhexyl)-benzene

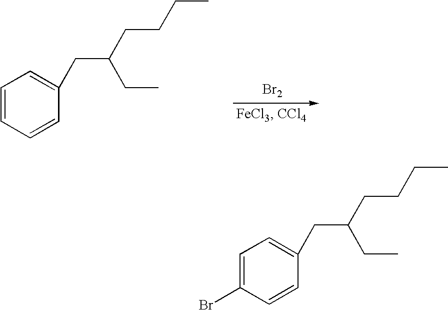

The procedure was adapted from Weinshenker, N. M. et al., J. Org. Chem. 1975, 40, 1966. A 100-mL round bottom flask was charged with (2-ethylhexyl)-benzene (12 g, 0.063 mol), carbon tetrachloride (20 mL), and anhydrous ferric chloride (0.10 g). A 3.9 mL solution of bromine (0.076 mol) in 10 mL of carbon tetrachloride was added. The resulting mixture was exothermic and proceeded with evolution of hydrogen bromide gas (and some bromine gas) that was neutralized with sodium hydroxide. The reaction was completed as the evolution of hydrogen bromide was finished. The solution was stirred at ambient temperature for an additional hour. After addition of aqueous sodium hydroxide (10%), the mixture was extracted with diethyl ether (3×100 mL). The combined organic layer was washed with aqueous sodium hydroxide (10%) until no yellow/brown color in the aqueous phase was observed. The organic phase was dried over anhydrous magnesium sulfate (MgSO₄). After the product was filtered, the solvent was removed by rotary evaporation. The crude product was distilled under vacuum to yield 13.8 g (81%) of colorless oil.

Spectral data: ¹H NMR (300 MHz, CDCl₃): δ_{H}0.96 (t, J=6 Hz, 6H), 1.29 (m, 8H), 1.86 (m, 1H), 2.51 (d, J=6 Hz, 2H), 7.01 (d, J=9 Hz, 2H), 7.38 (d, J=9 Hz, 2H).

### EXAMPLE 1c

### Synthesis of 3-[4-(2-ethylhexyl)-phenyl]-thiophene

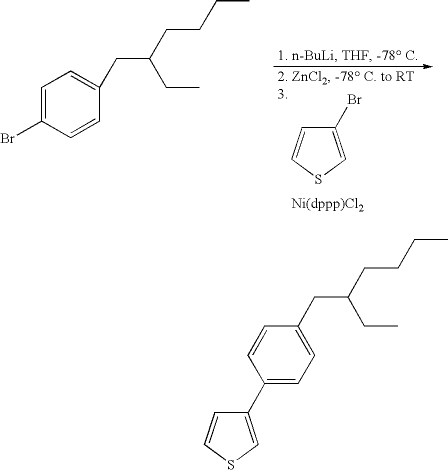

A dry 250-mL three-neck round bottom flask, equipped with a condenser, was charged with 1-bromo-4-(2-ethylhexyl)-benzene (8 g, 0.03 mol) and purged with N₂ followed by addition of anhydrous THF (50 mL) via a deoxygenated syringe. The reaction flask was cooled to −78° C. and n-butyllithium. A 2.5 M solution in hexane (12 mL, 0.03 mol) was added dropwise via syringe. The reaction mixture was stirred for 1 hour at −78° C. Anhydrous ZnCl₂ (4.09 g, 0.03 mol) was added in one portion and completely dissolved after 30 minutes of stirring. The cooling bath was removed and the reaction mixture was allowed to warm to ambient temperature, whereupon 3-bromothiophene (5.38 g, 0.033 mol) and Ni(dppp)Cl₂ (0.32 g) were added. The solution was heated up to reflux and maintained at that temperature for 12 hours, then cooled to ambient temperature, and quenched with cold HCl (10 mL, 1.0 N). The aqueous layer was separated and extracted with diethyl ether (3×100 mL). The organic phase was collected and dried over anhydrous magnesium sulfate (MgSO₄). After the product was filtered, the solvent was removed by rotary evaporation. The crude product was purified by recrystallization from methanol affording 5.3 g (65%) of white solid.

Spectral data: ¹H NMR (300 MHz, CDCl₃): δ_{H}0.87 (t, J=6 Hz, 6H), 1.27 (m, 8H), 1.56 (m, 1H), 2.53 (d, J=8.1 Hz, 2H), 7.15 (d, J=9 Hz, 2H), 7.37 (m, 3H), 7.48 (d, J=9 Hz, 2H).

### EXAMPLE 1d

### Synthesis of 2-bromo-3-[4-(2-ethylhexyl)-phenyl]-thiophene

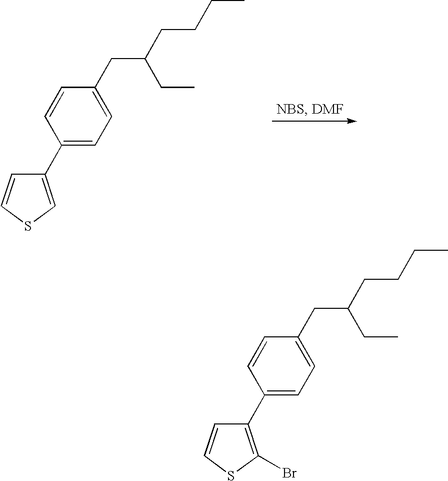

A 250-mL round bottom flask was charged with 3-[4-(2-ethylhexyl)-phenyl]-thiophene (7 g, 0.026 mol), N,N-dimethyl formamide (DMF) (65 mL). The reaction mixture was stirred at ambient temperature for 5 minutes, whereupon a 0.4 M solution of NBS (0.026 mol) in DMF was added and the stirring continued for 2 hours. After addition of water, the mixture was extracted with diethyl ether (3×150 mL). The combined organic layer was dried over anhydrous magnesium sulfate (MgSO₄). After the product was filtered, the solvent was removed by rotary evaporation. The crude product was purified using column chromatography on silica gel with hexane as the eluent (R_{f}=0.35). The compound was dried under vacuum to yield 8.7 g (95%) of slightly yellow oil.

Spectral data: ¹H NMR (300 MHz, CDCl₃): δ_{H}0.87 (t, J=6 Hz, 6H), 1.27 (m, 8H), 1.58 (m, 1H), 2.55 (d, J=7.5 Hz, 2H), 7.02 (d, J=6 Hz, 1H), 7.19 (d, J=9 Hz, 2H), 7.27 (d, J=6 Hz, 1H), 7.45 (d, J=9 Hz, 2H).

### EXAMPLE 1e

### Synthesis of 2-bromo-3-[4-(2-ethylhexyl)-phenyl]-5-iodothiophene

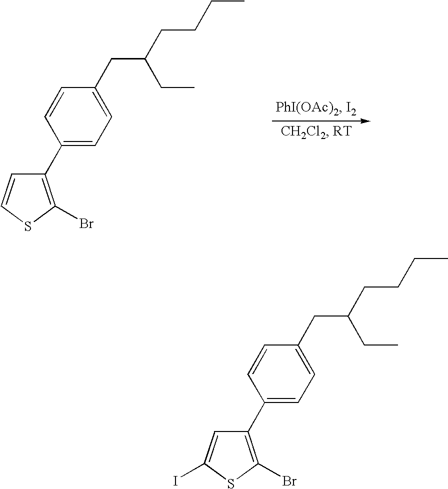

The procedure was adapted from Yokoyama, A. Macromolecules 2004, 37, 1169. A 100-mL round bottom flask was charged with 2-bromo-3-[4-(2-ethylhexyl)-phenyl]-thiophene (2.6 g, 7.4 mmol), purged with N₂, and anhydrous dichloromethane (18 mL) was added via a deoxygenated syringe. The reaction flask was cooled down to 0° C., whereupon iodine (I₂) (1.04 g, 4.1 mmol) and iodobenzene diacetate (PhI(OAc)₂) (1.4 g, 4.4 mmol) were added in one portion, and the mixture was stirred at ambient temperature for 4 hours. An aqueous solution of sodium thiosulfate (NaS₂O₃) (10%) was added to the reaction mixture; the aqueous layer was separated and extracted with diethyl ether (3×50 mL). The collected organic phase was washed with aqueous NaS₂O₃ (10%) and dried over anhydrous MgSO₄. After filtration, the solvent and iodobenzene were removed by evaporation under reduced pressure. The crude product was purified using column chromatography on silica gel with hexane as the eluent (R_{f}=0.38). The compound was dried under vacuum to yield 3.35 g (95%) of slightly yellow oil.

Spectral data: ¹H NMR (300 MHz, CDCl₃): δ_{H}0.87 (t, J=6 Hz, 6H), 1.28 (m, 8H), 1.6 (m, 1H), 2.6 (d, J=7.5 Hz, 2H), 7.19 (d, J=9 Hz, 2H), 7.18 (s, 1H), 7.39 (d, J=9 Hz, 2H).

### WORKING EXAMPLE 2

The following polymer, poly(3-[4-(2-ethylhexyl)-phenyl]thiophene), was prepared via the modified McCullough method:

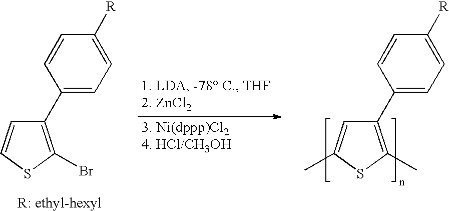

A dry 100-mL three-neck flask was flushed with N₂ and was charged with diisopropylamine (0.50 mL, 3.5 mmol) and anhydrous THF (30 mL), both of which were added via syringe. The reaction flask was cooled to 0° C. and n-butyllithium (2.0 mL, 3 mmol) was added dropwise via syringe. After 20 minutes of stirring at 0° C., the solution was chilled to —76° C. (acetone/dry ice bath), and stirring continued for 5 minutes. To this reaction mixture a previously chilled to −76° C. 0.3 M solution of 2-bromo-3-[4-(2-ethylhexyl)-phenyl]thiophene (1.05 g, 3 mmol) in anhydrous THF (10 mL) was added via cannula. The reaction mixture was stirred for 1 hour at −76° C. Anhydrous ZnCl₂ (0.50 g, 3.6 mmol) was added in one portion and completely dissolved after 30 minutes of stirring. The cooling bath was removed and the reaction mixture was allowed to warm to ambient temperature, at which time a suspension of Ni(dppp)Cl₂ (10 mg, 0.016 mmol) in THF (0.01 M) was added via syringe. The reaction mixture was heated to reflux and stirred for 24 hours. Hydrochloric acid (5 N) was added and the reaction mixture was precipitated into methanol. The polymer was filtered, washed in sequence with more methanol and hexanes, and dried under vacuum to yield the product as a dark orange-red solid (60-83%): Mₙ=15,640; M_{w}=44,500; PDI=2.8 (GPC: CHCl₃, λₘₐₓ=254 nm, 35° C.).

### WORKING EXAMPLE 3

The following polymer, poly(3-[4-(2-ethylhexyl)-phenyl]thiophene), was prepared via the modified GR1M method utilizing 2-bromo-3-[4-(2-ethylhexyl)phenyl]-5-iodothiophene:

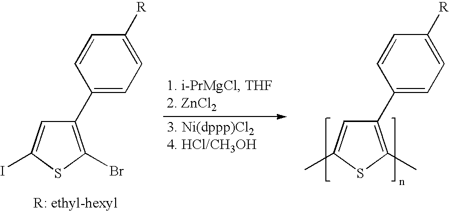

A dry 100-mL three-neck flask was charged with 2-bromo-3-[4-(2-ethylhexyl)phenyl]-5-iodothiophene (1.43 g, 3 mmol) and flushed with N₂, and THF (20 mL) was added via syringe. A 2 M solution of iso-propylmagnesium chloride (1.5 mL, 3 mmol) in THF was added via a deoxygenated syringe and the reaction mixture was stirred at ambient temperature for 10 minutes. Anhydrous ZnCl₂ (0.45 g, 3.3 mmol) was added in one portion and completely dissolved after 30 minutes of stirring. A suspension of Ni(dppp)Cl₂ (8 mg, 0.014 mmol) in THF (0.01 M) was added via syringe. The reaction mixture was heated to 55° C. and stirred for 12 hours. Hydrochloric acid (5 N) was added and the reaction mixture was precipitated into methanol. The polymer was filtered, washed in sequence with more methanol and hexanes, and dried under vacuum to yield the product as a dark orange solid (60-83%): Mₙ=9,000; M_{w}=12,600; PDI=1.4 (GPC: CHCl₃, λₘₐₓ=254 nm, 35° C.).

### WORKING EXAMPLE 4

The following polymer, poly(3-[4-(2-ethylhexyl)-phenyl]thiophene), was prepared via the Universal GRIM method utilizing 2-bromo-3-[4-(2-ethylhexyl)phenyl]-5-iodothiophene:

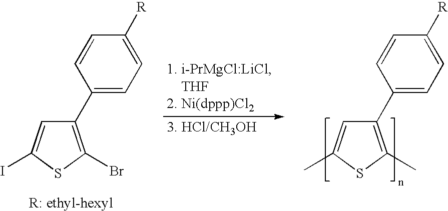

A dry, 100-mL, three-neck flask was charged with 2-bromo-3-[4-(2-ethylhexyl)phenyl]-5-iodothiophene (0.5 g, 1 mmol) and flushed with N₂, and THF (10 mL) was added via syringe. A 1-M solution of iso-propylmagnesium chloride:lithium chloride (1 mL, 1 mmol) in THF was added via a deoxygenated syringe and the reaction mixture was stirred at ambient temperature for 10 minutes. A suspension of Ni(dppp)Cl₂ (2 mg, 0.003 mmol) in THF (0.003 M) was added via syringe. The reaction mixture was heated to 55° C. and stirred for 2 hours. Hydrochloric acid (5 N) was added and the reaction mixture was precipitated into methanol. The polymer was filtered, washed in sequence with more methanol and hexanes, and dried under vacuum to yield the product as a dark orange solid (60-83%): Mₙ=46,900; M_{w}=57,000; PDI=1.2 (GPC: CHCl₃, λₘₐₓ=254 nm, 35° C.).

### EXAMPLE 5

### General Method for Making a Homopolymer

General procedure for preparation of phenyl-substituted polythiophenes via the GRIM method utilizing 2-bromo-3-[phenyl-substituted]-5-iodothiophene:

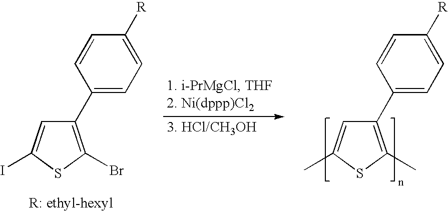

where R is a branched alkyl group.

In a typical polymerization experiment, a dry 100-mL three-neck flask was charged with 2-bromo-3-[4-(2-ethylhexyl)phenyl]-5-iodothiophene (0.5 g, 1 mmol) and flushed with N₂, and THF (10 mL) was added via syringe. A 2-M solution of iso-propylmagnesium chloride (0.5 mL, 1 mmol) in THF was added via a deoxygenated syringe and the reaction mixture was stirred at ambient temperature for 10 minutes. A suspension of Ni(dppp)Cl₂ (2 mg, 0.003 mmol) in THF (0.003 M) was added via syringe. The reaction mixture was heated to 55° C. and stirred for 2 hours. Hydrochloric acid (5 N) was added and the reaction mixture was precipitated into methanol. The polymer was filtered, washed in sequence with more methanol and hexanes, and dried under vacuum. The molecular weight of the polymer was measured by GPC.

### WORKING EXAMPLE 6

### Synthesis of poly(3-hexylthiophene)-b-poly{3-[4-(2-ethylhexyl)-phenyl]thiophene} Via Chain Extension Polymerization Utilizing the GRIM Method and the Universal GRIM Method

The block-copolymer, poly(3-hexylthiophene)-b-poly{3-[4-(2-ethylhexyl)-phenyl]thiophene} (P3HT-PPEHPT), was prepared via a combination of the GRIM and Universal GRIM methodologies utilizing 2-bromo-3-hexyl-5-iodothiophene and 2-bromo-3-[4-(2-ethylhexyl)phenyl]-5-iodothiophene, as shown below.

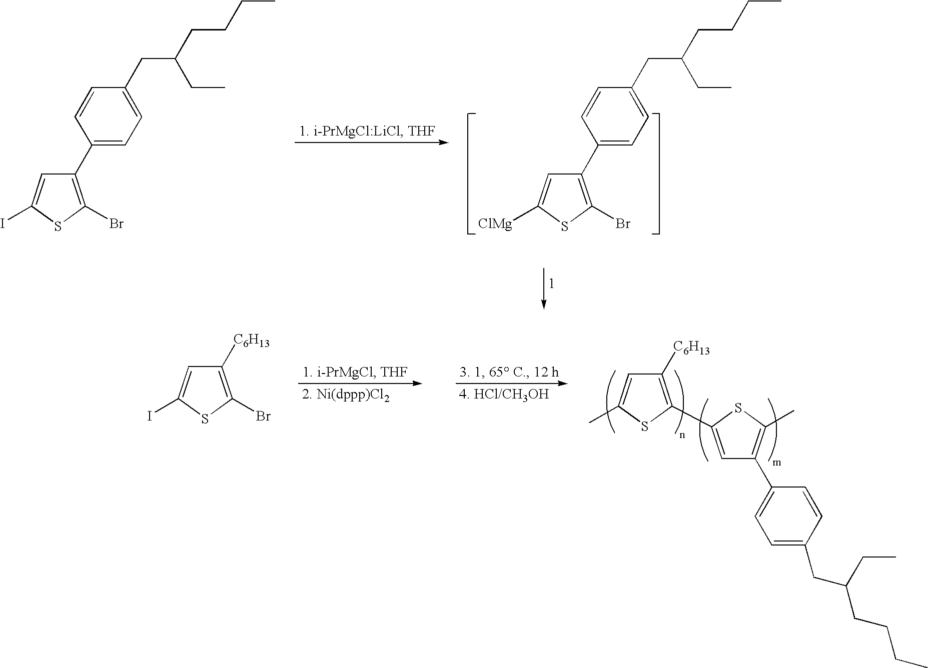

A dry 25-mL three-neck round bottom flask was flashed with N₂ and charged with 2-bromo-3-[4-(2-ethylhexyl)phenyl]-5-iodothiophene (0.67 g, 1.4 mmol) and anhydrous THF (5.0 mL) via syringe. A 1 M solution of iso-propylmagnesium chloride:lithium chloride (1.3 mL, 1.4 mmol) in THF was added via a deoxygenated syringe and the reaction mixture (1) was kept stirring at ambient temperature for the next step. Another dry 100-mL three-neck round bottom flask equipped with a condenser was flashed with N₂ and charged with 2-bromo-3-hexyl-5-iodothiophene (0.26 g, 0.7 mmol), dodecane (0.1 mL) (internal standard), and anhydrous THF (23 mL) via syringe. A 2 M solution of iso-propylmagnesium chloride (0.34 mL, 0.7 mmol) in THF was added via a deoxygenated syringe and the reaction mixture was stirred at ambient temperature for 10 minutes. A suspension of Ni(dppp)Cl₂ (5.2 mg, 9.6×10⁻⁶ mmol) in THF (0.01 M) was added via syringe. The reaction mixture was heated to 35° C. and stirred for 45 minutes, whereupon the content of the first flask (1) was introduced to the polymerization flask via a deoxygenated syringe. The reaction mixture was heated to 55° C. and stirred for 16 hours. Hydrochloric acid (5 N) was added and the reaction mixture was precipitated into methanol. The polymer was filtered, washed in sequence with more methanol and hexanes, and dried under vacuum to yield the product as a dark purple solid (50%): Mₙ=34,800; M_{w}=85,500; PDI=2.5 (GPC: CHCl₃, λₘₐₓ=254 nm, 35° C.).

### EXAMPLE 7

### General Procedure for Polymerization of poly(3-[X-aryl]thiophene)s, where X is a Branched Alkyl Group at Para, Ortho or Meta Position, Via the GRIM Method

Poly(3-[X-aryl]thiophene)s, where X is a branched alkyl group, are synthesized utilizing 2-bromo-(3-[X-aryl]thiophene)-5-iodo-thiophene precursors.

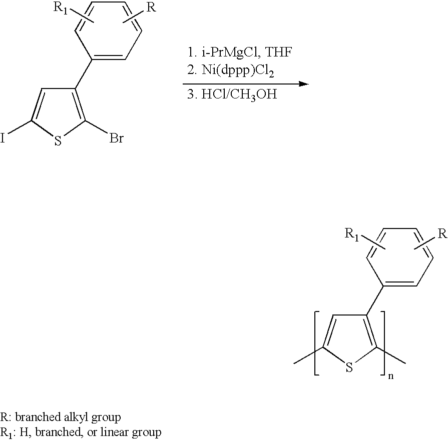

In a typical polymerization experiment, a dry 100-mL three-neck flask equipped with a condenser is charged with 2-bromo-(3-[p-X-aryl]thiophene)-5-iodo-thiophene (1 mmol) and flushed with N₂, and THF (10 mL) is added via syringe. A 2 M solution of iso-propylmagnesium chloride (1 mmol) in THF is added via a deoxygenated syringe and the reaction mixture is stirred at ambient temperature for 10 minutes. A suspension of Ni(dppp)Cl₂ (0.2-2 mol %) in THF (0.01 M) is added via syringe. The reaction mixture is heated to 55° C. and stirred for 2 to 12 hours. Hydrochloric acid (5 N) is added and the reaction mixture is precipitated into methanol. The polymer is filtered, washed in sequence with more methanol and hexanes, and dried under vacuum. The molecular weight of the polymer is measured by GPC.

### EXAMPLE 8

### General Procedure for Polymerization of poly(3-[X-aryl]thiophene)s, where X is a Branched Alkyl Group at the Para, Ortho or Meta Position, Via the Universal GRIM Method

Poly(3-[X-aryl]thiophene)s, where X is a branched alkyl group, are synthesized utilizing 2-bromo-(3-[X-aryl]thiophene)-5-iodo-thiophene precursors.

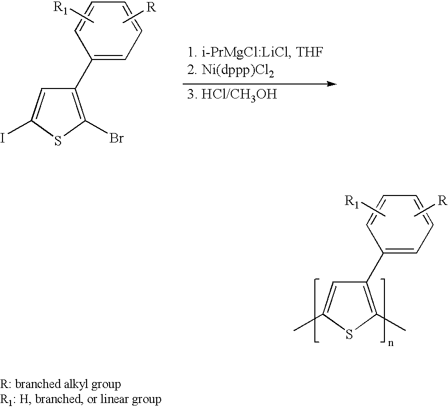

In a typical polymerization experiment, a dry 100-mL three-neck flask equipped with a condenser is charged with 2-bromo-(3-[p-X-aryl]thiophene)-5-iodo-thiophene (4.2 mmol) and flushed with N₂, and THF (42 mL) is added via syringe. A 1 M solution of iso-propylmagnesium chloride:lithium chloride (4.2 mmol) in THF is added via a deoxygenated syringe and the reaction mixture is stirred at ambient temperature for 10 minutes. A suspension of Ni(dppp)Cl₂ (0.2-2 mol %) in THF (0.01 M) is added via syringe. The reaction mixture is heated to 55° C. and stirred for 2 to 12 hours. Hydrochloric acid (5 N) is added and the reaction mixture is precipitated into methanol. The polymer is filtered, washed in sequence with more methanol and hexanes, and dried under vacuum. The molecular weight of the polymer is measured by GPC.

### EXAMPLE 9

### General Procedure for Synthesis of 3-alkyl-functionalized and 3-[X-aryl]thiophene copolymers, where X is Either Branched or Linear Alkyl Group at the Para, Ortho or Meta Position, Via the Universal GRIM Method

Copolymers of poly(3-alkyl-thiophene)-b-poly(3-[X-aryl]thiophene)s, where X is either branched or linear alkyl group, are synthesized utilizing 2-bromo-3-alkyl-5-iodothiophenes and 2-bromo-(3-[X-aryl]thiophene)-5-iodo-thiophene precursors.

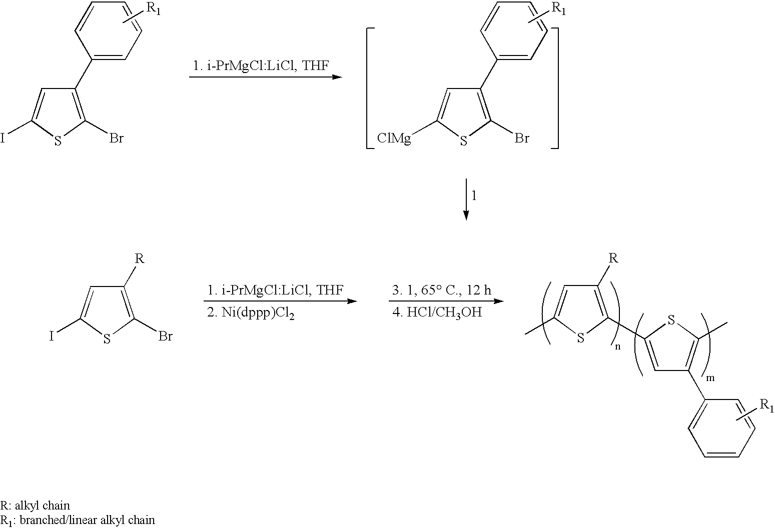

A dry 25-mL three-neck round bottom flask is flashed with N₂ and charged with bromo-(3-[X-aryl]thiophene)-5-iodo-thiophene (1.8 mmol) and anhydrous THF (6.0 mL) via syringe. A 1 M solution of iso-propylmagnesium chloride:lithium chloride (1.8 mmol) in THF is added via a deoxygenated syringe and the reaction mixture (1) is kept stirring at ambient temperature for the next step. Another dry 100-mL three-neck round bottom flask equipped with a condenser is flashed with N₂ and charged with 2-bromo-3-alkyl-5-iodothiophene (1.0 mmol), dodecane (0.1 mL) (internal standard), and anhydrous THF (31 mL) via syringe. A 1 M solution of iso-propylmagnesium chloride:lithium chloride (1.0 mmol) in THF is added via a deoxygenated syringe and the reaction mixture is stirred at ambient temperature for 10 minutes. A suspension of Ni(dppp)Cl₂ (0.2-2 mol %) in THF (0.01 M) is added via syringe. The reaction mixture is heated to 35° C. and stirred for 45 minutes, whereupon the content of the first flask (1) is introduced to the polymerization flask via a deoxygenated syringe. The reaction mixture is heated to 55° C. and stirred for 24 hours. Hydrochloric acid (5 N) is added and the reaction mixture is precipitated into methanol. The polymer is filtered, washed in sequence with more methanol and hexanes, and dried under vacuum. The molecular weight of the polymer is measured by GPC.

### WORKING EXAMPLE 10

### Thermochromism Reduction in Aryl-Substituted Polythiophenes, wherein the Aryl Group has a Branched Alkyl Substituent

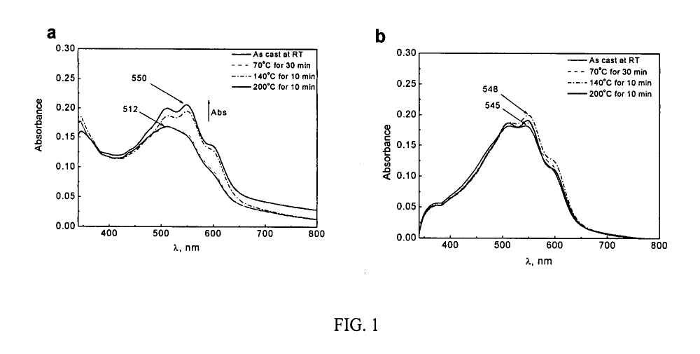

Various polymer films were spin-coated onto a substrate and, optionally, annealed at different temperatures and for different durations in a nitrogen atmosphere. The films were cast from solutions of either poly{3-[4-(2-ethylhexyl)phenyl]thiophene} (PEHPT) or poly[3-(4-octylphenyl)thiophene] (POPT) in chlorobenzene. In some instances, the films included PCBM as an n-type component. In other instances, the films were free of n-type component. Those films that included PCBM were formulated to a 1.2:1 weight ratio polymer:n-type blend. The UV-Vis-NIR spectra for the films are shown in FIGS. 1-3.

FIG. 1 shows the UV-Vis-NIR spectra of spin cast films from chlorobenzene of: (a) a poly{3-[4-(2-ethylhexyl)phenyl]thiophene} and [6,6]-phenyl-C61-butyric acid methyl ester (PCBM) blend (1.5:1) before and after annealing at various temperatures; and (b) poly{3-[4-(2-ethylhexyl)phenyl]thiophene} before and after annealing at various temperatures.

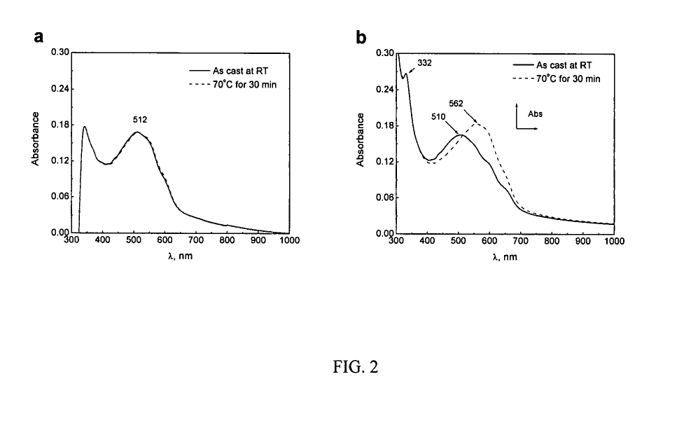

FIG. 2 shows UV-Vis-NIR spectra of spin cast films from chlorobenzene of: (a) a poly{3-[4-(2-ethylhexyl)phenyl]thiophene} and [6,6]-phenyl-C61-butyric acid methyl ester (PCBM) blend (1.5:1) before and after annealing; and (b) a poly[3-(4-octylphenyl)thiophene] and [6,6]-phenyl-C61-butyric acid methyl ester (PCBM) blend (1.5:1) before and after annealing.

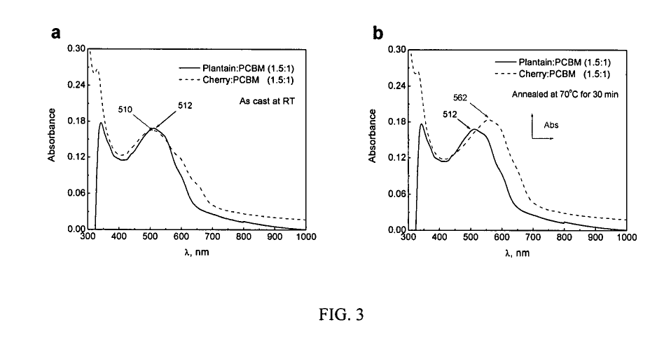

FIG. 3 shows UV-Vis-NIR spectra of spin cast films from chlorobenzene of p/n composite blends (1.5:1) of poly{3-[4-(2-ethylhexyl)phenyl]thiophene} and poly[3-(4-octylphenyl)thiophene] with [6,6]-phenyl-C61-butyric acid methyl ester (PCBM) before (a) and after annealing (b).

As is evident from FIGS. 1-3, the PEHPT films exhibit zero thermochromism, or reduced thermochromism, relative to POPT, over a significant temperature range. FIG. 1(b) shows that a PEHPT film exhibits substantially zero thermochromism for annealing temperatures up to 200° C. relative to the as-cast film. In contrast, it is well-known that POPT films exhibit a remarkable thermochromism over a significant temperature range. See, for example, Pei, Q., et al., Macromolecules 1992, 25, 4297; (b) Andersson, M. R., et al., Macromolecules 1994, 27, 6503.

FIG. 1(a) shows that the PEHPT:PCBM film exhibits some thermochromism when annealing takes place at high temperatures (e.g., 140° C. or higher). However, FIGS. 2 and 3 clearly show that the thermochromism exhibited by the PEHPT:PCBM film is substantially less that that exhibited by the POPT:PCBM film, at least at lower annealing temperatures. The increase in thermochromism at the higher temperatures is likely due to the rearrangement of the polymer at the higher temperatures. This is evidenced by the increase in absorbance and appearance of vibronic structure in the spectra, indicating improved inter-chain rearrangement, increased packing density, planarity, and crystallinity. The spectra further reveal a slight shift in the absorbance edge (i.e., absorbance onset occurs at higher energy) indicating a smaller E_{g} is achieved at 140° C. This feature remains and does not change when the annealing temperature is increased to 200° C. These data may be explained by an increase in the π-conjugation length in PEHPT leading to a decrease in the bandgap, which occurs at higher temperatures and remains more or less constant. As illustrated in Examples 10 and 11, this can have a beneficial effect on OPV device performance.

Without wishing or intending to be bound by any particular theory of the invention, the inventors believe that the reduced thermochromism observed for PEHPT relative to POPT may be explained as follows. Both polymers have the rigid phenylene ring attached to the backbone of the thiophene rings (that influences the conjugated length of the polymers, bandgap, energy levels, etc.) and because of that substitution, both polymers are non-planar at room temperature (FIG. 3a); however, in POPT, the temperature induced movement of the alkyl side chains has a more pronounced effect on the torsion angles of the phenylene rings and the thiophene rings (Xing, K. Z., et al., Synthetic Metals 1996, 80, 59) when compared to the effect of the branched side chains on the thiophene rings in PEHPT. The lack of the ethyl-substituent in the sidegroup of POPT may allow POPT to pack more efficiently and thus allow for more ordered alignment of the pendant phenyl rings with: 1) each other; and/or 2) the thiophene backbone. Both of these scenarios would allow for the thermochromic behavior exhibited in POPT and not in PEHPT.

In addition, POPT has a smaller bandgap than PEHPT and this bandgap continuously narrows at elevated temperatures indicating that the torsion angle between the thiophene rings continuously decreases as the polymer chain tries to adopt a more planar conformation. Thus, the π-conjugation length of the polymer continuously increases resulting in the continuous change in the π-band structure of the polymer that dramatically affects the OPV device performance.

### WORKING EXAMPLE 11

### Fabrication of an Organic Photovoltaic Cell from a Polymer

The photovoltaic devices comprise patterned indium tin oxide (ITO, anode, 60 Ω/square) on glass substrate (Thin Film Devices, Anaheim, Calif.); a thin layer of HIL (30 nm thick) consisting of PEDOT/PSS (Baytron, AI 4083, HC Stark); a 100- to 200-nm layer of PEHPT (as prepared via the modified McCullough method described in Example 2) blended with methanofullerence [6,6]-phenyl C61-butyric acid methyl ester (PCBM) (Nano-C, Westwood, Mass.) (an n-type component); and a Ca/Al bilayer cathode.

The patterned ITO glass substrates were cleaned with detergent, hot water, and organic solvents (acetone and alcohol) in an ultrasonic bath and treated with ozone plasma immediately prior to device layer deposition. The HIL solution was then spin-coated onto the patterned ITO glass substrate to achieve a thickness of 30 nm. The film was dried at 150° C. for 30 minutes in a nitrogen atmosphere. The active layer was formulated to a 1.2:1 or 1.5:1 weight ratio polymer:n-type blend in chlorobenzene. The formulation was made to 0.024% volume solids and was then spun onto the top of the HIL film, resulting in no damage to the HIL (verified by AFM). The film was then annealed in the range of 175° C. to 200° C. for 30 minutes in a glove box. Next, a 5-nm Ca layer was thermally evaporated onto the active layer through a shadow mask, followed by deposition of a 150-nm Al layer. The devices were then encapsulated via a glass cover slip (blanket). Encapsulation was sealed with EPO-TEK OG112-4 UV curable glue. The encapsulated device was cured under UV irradiation (80 mW/cm²) for 4 minutes and tested as follows.

The photovoltaic characteristics of devices under white light exposure (Air Mass 1.5 Global Filter) were measured using a system equipped with a Keithley 2400 source meter and an Oriel 300 W Solar Simulator based on a Xe lamp with output intensity of 100 mW/cm² (AM1.5G). The light intensity was set using an NREL-certified Si—KG5 silicon photodiode.

The power conversion efficiency of a solar cell is given as η=(FF_{|}J_{sc|}V_{oc})/Pᵢₙ, where FF is the fill factor, J_{sc} is the current density at short circuit, V_{oc} is the photovoltage at open circuit and Pᵢₙ is the incident light power density. The J_{sc}, V_{oc} and efficiency (η%) measured for each OPV device (e.g., a standard OPV device with an ITO/PEDOT:PSS/Active Layer/Ca/Al configuration, where Active Layer is comprised of a p/n composite deposited from a single solvent system) are shown in Table 1, below, compared to the control device which was made as described above using poly(3-hexylthiophene) as the p-type and PCBM as the n-type materials. The data clearly show a significant improvement in the V_{oc} for the OPV cell made with EPHT or P3HT-PPEHPT, compared to the OPV cell made with P3HT.

TABLE 1

| p-type | | n-type | p/n | | J_{SC} | V_{OC} | | | Method of |
|---|---|---|---|---|---|---|---|---|---|
| polymer | Mn (PDI)¹ | component | ratio | Solvent² | (mA/cm²) | (V) | FF | η(%) | Synthesis³ |
| P3HT | 52,500 (1.5) | PCBM | 1.2:1 | DCB | 10.02 | 0.58 | 0.65 | 3.75 | GRIM (Br/Br) |
| PEHPT | 15,600 (2.8) | PCBM | 1.5:1 | CB | 4.18 | 0.78 | 0.45 | 1.47 | McCullough (Br) |
| PEHPT | 15,600 (2.8) | Indene | 1.2:1 | CB | 4.83 | 0.86 | 0.57 | 2.44 | McCullough (Br) |
| | | mono-C60 | | | | | | | |
| PEHPT | 15,600 (2.8) | Indene bis- | 1.2:1 | CB | 3.32 | 1.02 | 0.52 | 1.77 | McCullough (Br) |
| | | C60 | | | | | | | |
| PEHPT | 9,300 (1.2) | PCBM | 1.2:1 | CB | 3.19 | 0.72 | 0.41 | 0.94 | GRIM |
| PEHPT | 19,500 (1.3) | PCBM | 1.2:1 | CB | 4.37 | 0.69 | 0.65 | 1.96 | Universal GRIM |
| | | | | | | | | | (I/Br) |
| PEHPT | 43,000 (1.3) | PCBM | 1.2:1 | CB | 5.29 | 0.70 | 0.58 | 2.12 | Universal GRIM |
| | | | | | | | | | (I/Br) |
| P3HT- | 25,000 (1.8) | PCBM | 1.2:1 | CB | 8.23 | 0.62 | 0.66 | 3.34 | GRIM (I/Br) |
| PPEHPT | | | | | | | | | |
| P3HT- | 25,000 (1.8) | Indene bis- | 1.2:1 | CB | 4.89 | 0.89 | 0.52 | 2.28 | GRIM (I/Br) |
| PPEHPT | | C60 | | | | | | | |
| P3HT- | 25,000 (1.8) | Indene tris- | 1.2:1 | CB | 2.05 | 1.01 | 0.41 | 0.84 | GRIM (I/Br) |
| PPEHPT | | C60 | | | | | | | |

¹Number average molecular weight and polydispersity index (Mₙ and PDI, respectively) were determined via Gel Permeation Chromatography (GPC) with chloroform as the eluent (flow rate 1.0 mL/min, 35° C., λ = 254 nm) against polystyrene standards with toluene used as an internal standard
²Solvent: dichlorobenzene (DCB); chlorobenzene (CB)
³A series of regioregular 3-alkyl/aryl-functionalized polythiophenes were synthesized via either the GRIM route [a) Lowe, R. S. et al. Adv. Mater. 1999, 11, 250; b) Iovu, M. C. et al., Macromolecules 2005, 38, 8649], the McCullough methodology [a) McCullough, R. D. et al., Synth. Met. 1995, 67, 279; b) Sheina, E. E., et al. Macromolecules 2004, 37, 3526], or the Universal GRIM [Iovu., M. C.; et al. US provisional patent application 60/841,548 filed Sep. 1, 2006; see also U.S. Regular Patent Application No. 11/849,229, filed on Aug. 31, 2007 to McCullough et al, its corresponding PCT/US2007/077461 published as WO2008/028166] utilizing dibrominated (Br/Br), monobrominated (Br), and iodo-bromominated (I/Br) monomer precursors, respectively.

### WORKING EXAMPLE 12

### Thermal Stability of Organic Photovoltaic Cells Incorporating Aryl-Substituted Polythiophenes, wherein the Aryl Group has a Branched Alkyl Substituent

OPV cells having the same device configuration as described above were fabricated using the procedure described in Example 11. The OPV cells were fabricated with active layers of either POPT or PEHPT as the p-type component with PCBM as the n-type component and chlorobenzene as a solvent. The active layers of the devices had different p/n ratios and were annealed at different temperatures, as indicated in Table 2. The p-type components for the active layers were synthesized using either the GRIM or the McCullough method.

TABLE 2

| p-type | n-type | p/n | | Annealing | J_{SC} | | | | Method of |
|---|---|---|---|---|---|---|---|---|---|
| polymer¹ | component | ratio | Solvent² | T° C. (min) | mA/cm² | V_{OC} V | FF | η % | Synthesis³ |
| POPT | PCBM | 1.2:1 | CB | 110 (30) | 2.7 | 0.57 | 0.33 | 0.52 | GRIM |
| POPT | PCBM | 1.2~1 | CB | 175 (30) | 0.18 | 0.40 | 0.32 | 0.02 | GRIM |
| POPT | PCBM | 1.5~1 | CB | 70 (30) | 1.39 | 0.66 | 0.33 | 0.3 | GRIM |
| POPT | PCBM | 1.5~1 | CB | 135 (30) | 2.31 | 0.55 | 0.32 | 0.41 | GRIM |
| POPT | PCBM | 1.5:1 | CB | 175 (30) | 0.39 | 0.47 | 0.3 | 0.05 | GRIM |
| PEHPT | PCBM | 1.2~1 | CB | 175 (30) | 3.19 | 0.72 | 0.41 | 0.94 | GRIM |
| PEHPT | PCBM | 1.2~1 | CB | 175 (30) | 4.66 | 0.79 | 0.48 | 1.76 | McCullough |
| PEHPT | PCBM | 1.2~1 | CB | 200 (30) | 4.26 | 0.75 | 0.45 | 1.46 | McCullough |
| PEHPT | PCBM | 1.2~1 | CB | 200 (10) | 4.66 | 0.78 | 0.47 | 1.71 | McCullough |

¹GRIM-POPT [Mₙ = 17,000 (PDI = 3.4)]; GRIM-PEHPT [Mₙ = 9,300 (PDI = 1.2)]; McCullough-PEHPT [Mₙ = 15,600 (PDI = 2.8)]
²Solvent: chlorobenzene (CB)
³A series of regioregular 3-alkyl/aryl-functionalized polythiophenes were synthesized via either the GRIM route [a) Lowe, R. S. et al. Adv. Mater. 1999, 11, 250; b) Iovu, M. C., et al. Macromolecules 2005, 38, 8649] or the McCullough methodology [a) McCullough, R. D.; et al. Synth. Met. 1995, 67, 279; b) Sheina, E. E., Macromolecules 2004, 37, 3526]. Number and weight average molecular weights (Mₙ and M_{w}, respectively) were determined via Gel Permeation Chromatography (GPC) with chloroform as the eluent (flow rate 1.0 mL/min, 35° C., λ = 254 nm) against polystyrene standards with toluene used as an internal standard.

The superior thermal stability of PEHPT relative to POPT is evident from the OPV device data. It can be seen from the results in Table 2 that high temperatures were detrimental to the device performance where active layer was comprised of POPT whereas OPV cells incorporating PEHPT exhibited relatively high efficiencies (e.g., η%≧1, ≧1.4, or even ≧1.7) even after being annealed at 200° C.

### WORKING EXAMPLE 13

### Improved Methods for the Production of POPT

In addition to improved aryl-substituted conjugated polymers, improved methods for producing POPT are provided. Specifically, it has been discovered that the properties of POPT can be improved when POPT is produced using a GRIM, modified GRIM, McCullough, or modified McCullough methods. This Example and Example 14, below, illustrate improved methods for producing POPT and methods for making copolymers thereof.

The following block-copolymer, poly[(3-butylthiophene)-b-(3-(4-octylphenyl)thiophene], was prepared via a combination of the modified GRIM and McCullough methodologies:

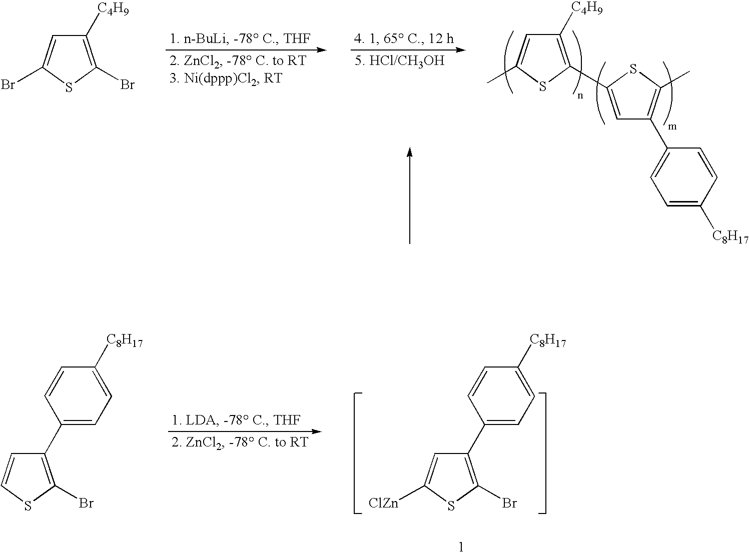

A dry 25-mL three-neck round bottom flask was flashed with N₂ and charged with 2-bromo-3-(4-octylphenyl)thiophene (1.2 g, 3.5 mmol) and anhydrous THF (4 mL) via syringe. The reaction flask is chilled to −76° C. for the next step.

A dry 25-mL three-neck flask was flushed with N₂ and charged with diisopropylamine (0.57 mL, 4.1 mmol) and anhydrous THF (8 mL), in which both were added via syringe. The reaction flask was cooled to 0° C. and n-butyllithium (1.7 mL, 3.5 mmol) was added dropwise via syringe. After 20 minutes of stirring at 0° C., the solution was chilled to −76° C. (acetone/dry ice bath) and stirring continued for 5 minutes. To this reaction mixture a previously-chilled-to-76° C. 1 M THF solution of 2-bromo-3-(4-octylphenyl)thiophene was added via cannula. The reaction mixture was stirred for 1 hour at −76° C. Anhydrous ZnCl₂ (0.50 g, 3.6 mmol) was added in one portion and completely dissolved after 30 minutes of stirring. The cooling bath was removed and the reaction mixture (1) was allowed to warm to ambient temperature and was kept at ambient temperature for the next step.

Another 100-mL three-neck round bottom flask was flushed with N₂ and charged with 2,5-dibromo-3-butylthiophene (0.5 g, 1.7 mmol) and anhydrous THF (55 mL). A 2 M solution of n-butyllithium (0.85 mL, 1.7 mmol) was added via a deoxygenated syringe. The reaction mixture was stirred for 10 minutes. Anhydrous ZnCl₂ (0.25 g, 1.87 mmol) was added in one portion and completely dissolved after 30 minutes of stirring. A suspension of Ni(dppe)Cl₂ (5.3 WASH_{—}4081453.1 mg, 0.010 mmol) in 1 mL of THF was added via syringe. The reaction mixture was stirred at ambient temperature for 10 minutes, at which point 1 was transferred to this 100-mL three-neck round bottom flask. The reaction mixture was heated to 65° C. and stirred for 12 hours. Hydrochloric acid (5 N) was added and the reaction mixture is precipitated into methanol. The polymer was filtered, washed in sequence with more methanol and hexanes, and dried under vacuum to yield the product as a dark orange solid (60-83%): Mₙ=11,000; M_{w}=17,600; PDI=1.6 (GPC: CHCl₃, λₘₐₓ=254 nm, 35° C.).

### WORKING EXAMPLE 14

General procedure for preparation of block copolymers of alkyl-substituted and phenyl-substituted polythiophenes via a combination of the GRIM and the Universal GRIM methodologies:

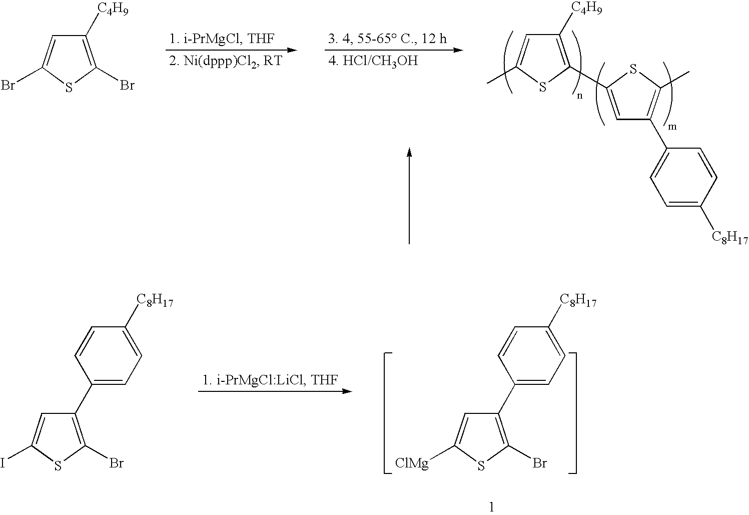

A dry 25-mL three-neck round bottom flask was flashed with N₂ and charged with 2-bromo-5-iodo-3-(4-octylphenyl)thiophene (1.7 g, 3.5 mmol) and anhydrous THF (12 mL) via syringe. A 1 M solution of iso-propylmagnesium chloride:lithium chloride (3.5 mL, 3.5 mmol) in THF was added via a deoxygenated syringe. The reaction mixture was stirred for 10 minutes at ambient temperature and the conversion of the monomer to the Grignard reagent was monitored by GC-MS analysis. The reaction flask (1) was kept at ambient temperature for the next step.

Another dry 100-mL three-neck round bottom flask was flushed with N₂ and charged with 2,5-dibromo-3-butylthiophene (0.5 g, 1.7 mmol) and anhydrous THF (55 mL). A 2 M solution of iso-propylmagnesium chloride (0.85 mL, 1.7 mmol) in THF was added via a deoxygenated syringe. The reaction mixture was stirred for 10 minutes. The conversion of 2,5-dibromo-3-butyllthiophene to 2-bromo-5-chloromagnesium-3-butylthiophene was monitored by the GC-MS analysis. At complete conversion, a suspension of Ni(dppe)Cl₂ (5.3 mg, 0.01 mmol) in 1 mL of anhydrous THF was added to the reaction flask via a deoxygenated syringe. The reaction mixture was stirred at ambient temperature for 10 minutes, at which point 1 was transferred to this 100-mL three-neck round bottom flask. The reaction mixture was heated to 65° C. and stirred for 12 hours. Hydrochloric acid (5 N) was added and the reaction mixture was precipitated into methanol. The polymer was filtered, washed in sequence with more methanol and hexanes, and dried under vacuum. The molecular weight of the polymer was measured by GPC.

Table 3 below provides a summary of material characteristics for the poly[3-(4-octylphenyl)thiophene] films produced as described in Examples 13 and 14 as a function of the method of synthesizing POPT. Also shown is the effect on the V_{OC} of an OPV cell having a POPT active layer, wherein the POPT layer is made using different methods of synthesis. For comparison, the results for a POPT film made using the well-known FeCl₃ method are also shown.

TABLE 3

| p-Type | | | | | | | Method of |
|---|---|---|---|---|---|---|---|
| polymer | Mw | PDI | HOMO eV | λₘₐₓ nm | Eg^{UV} eV | V_{OC} V | Synthesis |
| POPT | 44,300 | 1.6 | −5.22 | 558 | 1.77 | ~0.5 | FeCl₃ |
| POPT | 49,100 | 1.6 | −5.28 | 542 | 1.80 | ~0.6-0.7 | GRIM |
| POPT | 36,400 | 1.4 | −5.37 | 561 | 1.7 | ~0.45 | McCullough |
| POPT | 46,730 | 1.8 | −5.38 | 554 | 1.8 | ~0.6 | McCullough |

### ADDITIONAL EMBODIMENTS

Unexpectedly, improved compositions and organoelectronic devices can be obtained by control of the polymerization monomer and the resultant polymer. For example, one embodiment provides a composition comprising: at least one thiophene compound comprising a substituent at the 3-position, a first halogen substituent at the 2-position, and a second halogen at the 5-position, wherein the first and second halogens are different halogens. In one embodiment, for example, the first halogen is bromine and the second halogen in iodine. In one embodiment, the substituent at the 3-position comprises an aryl group bonded to the thiophene ring. In another embodiment, the substituent at the 3-position comprises an aryl group bonded to the thiophene ring, and the aryl group further comprises at least one alkyl group bonded to the aryl group. In another embodiment, the substituent at the 3-position comprises an aryl group bonded to the thiophene ring, and the aryl group further comprises at least one branched alkyl group bonded to the aryl group. Aryl and alkyl groups can be as described above.

Another embodiment is a polymer prepared by polymerization of at least one monomer, wherein at least one monomer comprises at least one thiophene compound comprising a substituent at the 3-position, a first halogen substituent at the 2-position, and a second halogen at the 5-position, wherein the first and second halogens are different halogens. The polymer can be a homopolymer, or the polymer can be a copolymer.

Another embodiment is a device comprising a polymer prepared by polymerization of at least one monomer, wherein at least one monomer comprises at least one thiophene compound comprising a substituent at the 3-position, a first halogen substituent at the 2-position, and a second halogen at the 5-position, wherein the first and second halogens are different halogens. The polymerization can be carried out without iron catalyst.

What is claimed is:

1. A polymer comprising a conjugated polymer backbone comprising heterocyclic repeat units and side groups, wherein at least some of the side groups comprise an aryl group comprising at least one branched alkyl group substituent.

2. The polymer of claim 1, wherein the conjugated polymer backbone comprises a homopolymer polymer backbone.

3. The polymer of claim 1, wherein the conjugated polymer backbone comprises a copolymer polymer backbone.

4. The polymer of claim 1, wherein the conjugated polymer backbone comprises a block copolymer backbone.

5. The polymer of claim 4, wherein the conjugated polymer backbone comprises at least one conjugated block and at least one non-conjugated block.

6. The polymer of claim 1, wherein the heterocyclic repeat units comprise thiophene rings.

7. The polymer of claim 6, wherein the side group comprising an aryl group is bound to the thiophene ring at the 3-position.

8. The polymer of claim 1, wherein the aryl group is bound directly to a heterocyclic ring in the conjugated polymer backbone.

9. The polymer of claim 7, wherein the aryl group is bound directly to a thiophene ring in the conjugated polymer backbone.

10. The polymer of claim 1, wherein the aryl group comprises at least two substituents.

11. The polymer of claim 10, wherein the aryl group comprises at least two branched aryl group substituents.

12. The polymer of claim 1, wherein the aryl group is a phenyl group.

13. The polymer of claim 1, wherein the branched alkyl group is substituted.

14. The polymer of claim 1, wherein the branched alkyl group is unsubstituted.

15. The polymer of claim 1, wherein the branched alkyl group comprises a C3-C20 alkyl group.

16. The polymer of claim 1, wherein the branched alkyl group comprises a C4-C12 alkyl group.

17. The polymer of claim 1, wherein the branched alkyl group comprises a C5-C10 alkyl group.

18. The polymer of claim 6, wherein the branched alkyl group comprises a C4-C20 alkyl group.

19. The polymer of claim 18, wherein the branched alkyl group comprises an ethyl hexyl group.

20. The polymer of claim 6, wherein the aryl group comprises two ethyl hexyl substituents.

21. The polymer of claim 1, wherein at least some of the heterocyclic repeat units comprises thiophene rings having the structure I: 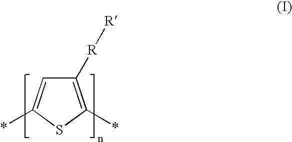
wherein R is an aryl group, R′ is a branched alkyl group and n represents the number of thiophene rings having the structure I.

22. The polymer of claim 21, wherein R is a phenyl group and R′ comprises a branched C4 to C20 alkyl group.

23. The polymer of claim 1, wherein the peaks in the absorbance spectrum of the polymer exhibit a bathochromic shift of no greater than 10 nm for the polymer as annealed at 70° C. for 30 minutes, relative to the polymer as cast at room temperature for polymer cast from a chlorobenzene solvent.

24. The polymer of claim 1, wherein the peaks in the absorbance spectrum of the polymer exhibit a bathochromic shift of no greater than 10 nm for the polymer as annealed at 200° C. for 10 minutes, relative to the polymer as cast at room temperature.

25. A polymer comprising a conjugated polymer comprising a backbone comprising heterocyclic repeat units and side groups, wherein at least some of the side groups comprise an aryl group comprising at least one alkyl group substituent, wherein the peaks in the absorbance spectrum of the polymer exhibit a bathochromic shift of no greater than 10 nm for the polymer as annealed at 70° C. for 30 minutes, relative to the polymer as cast at room temperature for polymer cast from a chlorobenzene solvent.

26. The polymer of claim 25, wherein the conjugated polymer is a polythiophene.

27. A composition comprising the polymer of claim 1 and an electron acceptor.

28. The composition of claim 27, wherein the electron acceptor comprises a fullerene or a fullerene derivative.

29. The composition of claim 28, wherein the electron acceptor comprises at least one indene derivative of a fullerene.

30. A polymer comprising a conjugated polymer backbone comprising thiophene repeat units, wherein at least some of the thiophene repeat units have an aryl side group at the 3-position and further wherein the aryl side groups comprise a branched alkyl group substituent.

31. The polymer of claim 30, wherein the at least one branched alkyl group substituent comprises an ethylhexyl group.

32. An electronic device comprising a polymer comprising a conjugated polymer backbone comprising heterocyclic repeat units and side groups, wherein at least some of the side groups comprise an aryl group comprising at least one branched alkyl group substituent.

33. The device of claim 32, wherein the heterocyclic repeat units comprise thiophene rings.

34. The device of claim 32, wherein the device is a photovoltaic cell comprising a first electrode, a second electrode, and an active layer disposed between the first and second electrodes, wherein the active layer comprises the polymer and an electron acceptor.

35. The device of claim 34, wherein the electron acceptor is a fullerene or a fullerene derivative.

36. The device of claim 32, wherein the device is a light emitting diode comprising a first electrode, a second electrode, an electroluminescent layer disposed between the first and second electrodes and at least one of a hole injection layer or hole transport layer disposed between one of the first and second electrodes and the electroluminescent layer.

37. The device of claim 35, wherein the electroluminescent layer comprises the polymer.

38. A monomer comprising a heterocyclic ring and a side group, wherein the side group comprises an aryl group comprising at least one branched alkyl group substituent.

39. The monomer of claim 38, wherein the heterocyclic ring is a thiophene ring.

40. The monomer of claim 38, wherein the branched alkyl group substituent is a C3-C20 alkyl group.

41. The monomer of claim 38, wherein the aryl group is a phenyl group.

42. The monomer of claim 38, wherein the aryl group is bound directly to the heterocyclic ring.

43. The monomer of claim 41, wherein the heterocyclic ring is a thiophene ring and the aryl group is bound to the heterocyclic ring at the 3-position.

44. The monomer of claim 37, wherein the heterocyclic ring is a thiophene ring and the branched alkyl group is an ethylhexyl group.

45. A method comprising:
polymerizing at least one heterocyclic monomer comprising an aryl group comprising at least one branched alkyl group substituent, to form a polymer comprising a conjugated polymer backbone comprising heterocyclic repeat units and side groups, wherein at least some of the side groups comprise an aryl group comprising at least one branched alkyl group substituent.

46. The method of claim 45, wherein the polymerizing is a copolymerizing including also polymerizing at least one heterocyclic monomer comprising an alkyl side group.
